(19) United States
(12) Patent Application Publication
(10) Pub. No.: US 2014/0290019 A1
(43) Pub. Date: Oct. 2, 2014

(54) METHOD FOR FABRICATING VIBRATOR

(71) Applicant: NIHON DEMPA KOGYO CO., LTD., Tokyo (JP)

(72) Inventor: MAKIKO NAKAMURA, SAITAMA (JP)

(73) Assignee: NIHON DEMPA KOGYO CO., LTD., Tokyo (JP)

(21) Appl. No.: 14/226,824

(22) Filed: Mar. 27, 2014

(30) Foreign Application Priority Data
Mar. 28, 2013 (JP) 2013-069428

(51) Int. Cl. H03H 3/02

(52) U.S. Cl. CPC H03H 3/02; H03H 2003/027
USPC 29/25.35

(57) ABSTRACT

A method for fabricating a vibrator with a vibrating plate and an electrode for vibrating the vibrating plate includes laminating, forming, filling-in, patterning, subsequently laminating, and subsequently etching. The forming forms a through hole that passes through a conductive film and a second sacrifice film and reaches at least a middle portion in a film thickness direction of a first sacrifice film. The filling-in fills in an auxiliary film for adjusting temperature characteristics including silicon and oxygen from a lower end position to an upper end position of the through hole. The subsequently etching etchs an upper end portion of the auxiliary film, a lower end portion of the auxiliary film, the first sacrifice film, the second sacrifice film, and a third sacrifice film, while leaving the auxiliary film inside the through hole on the vibrating plate, with a use of an etching fluid including hydrogen fluoride.

### CROSS-REFERENCE TO RELATED APPLICATION

This application claims the priority benefits of Japanese application serial no. 2013-069428, filed on Mar. 28, 2013. The entirety of the above-mentioned patent application is hereby incorporated by reference herein and made a part of this specification.

### FIELD OF THE INVENTION

This disclosure relates to a method for fabricating a vibrator that includes a vibrating plate and an electrode disposed around of this vibrating plate.

### DESCRIPTION OF THE RELATED ART

As an electrostatic drive type vibrator, there is known, for example, a disc resonator that has a disc (circular plate)-shaped vibrating plate and an electrode for vibrating this vibrating plate, disposed on a base substrate. To fabricate this vibrator, the so-called Micro Electro Mechanical System (MEMS) method is used, for example. This is a method for dry etching a polysilicon (Si) film and a silicon oxide (SiO₂) film while alternately laminating them. The polysilicon (Si) film constitutes a vibrating plate and an electrode, and the silicon oxide (SiO₂) film forms a sacrifice film. Wet etching the sacrifice film with the use of Hydrogen fluoride (HF) water solution or similar after the film formation process and dry etching process have been completed separates the vibrating plate and the electrode from each other as well as supports the vibrating plate in a state where the vibrating plate floats above the base substrate. In order to configure such a vibrator to run at a voltage as low as possible, that is, to facilitate an electrostatic bond between the electrode and the vibrating plate, it is preferred to bring the electrode and the vibrating plate as close to each other as possible.

The polysilicon that constitutes the above-described vibrating plate has an approximately 20 to 40 ppm/° C. frequency variation against a temperature change. Constituting the vibrating plate with polysilicon will resultantly produce more variable frequency characteristics depending on the temperature of an atmosphere where the vibrator is placed. For the above reason, combining silicon oxide with a vibrating plate as an auxiliary film for reducing the frequency variation in constituting the vibrating plate is being examined. Silicon oxide has temperature characteristics that cancel the temperature characteristics of polysilicon. Specifically, the frequency of silicon oxide decreases as the frequency of polysilicon increases in response to a temperature change, while the frequency of silicon oxide increases as the frequency of polysilicon decreases.

However, forming an auxiliary film made up of silicon oxide on a surface of the vibrating plate after conducting, for example, the above-described wet etching process will make it harder to constitute a low voltage drive type vibrator because the electrode and the vibrating plate need to be separated from each other in advance for the auxiliary film. On the other hand, forming the auxiliary film before forming and dry etching a polysilicon film and a sacrifice film are complete will remove the whole or a part of the auxiliary film in a subsequent wet etching process. For a vibrating plate that vibrates in a lateral direction, a varied film thickness dimension of the auxiliary film in a height direction may possibly result in a non-uniform vibration inside the vibrating plate. On the other hand, using a material such as Germanium (Ge), which is insoluble to hydrogen fluoride and removable with a flux that does not dissolve polysilicon, as the above-described sacrifice film would increase the material cost.

Japanese Unexamined Patent Application Publication No. 2010-35144 (paragraph 0070) discloses a technique for forming a silicon oxide film at a vibrating portion. Japanese Unexamined Patent Application Publication No. 2009-160728 (paragraph 0034) discloses a technique for filling a groove 3 with a fixing material such as SiN or SiO₂ in forming a machine component in the MEMS method. Japanese Unexamined Patent Application Publication No. 7-122791 discloses a technique for etching SrTiO3 in isopropyl alcohol-diluted HF solution. Japanese Unexamined Patent Application Publications No. 2002-353443 (paragraphs [0006] and [0007]) and 2011-228338 (paragraphs 0076 and 0077) disclose that an etching rate is different between an NSG film and a BPSG film when such solution is used. However, the above-described problems are not examined in these patent documents.

A need thus exists for a method for fabricating a vibrator which is not susceptible to the drawback mentioned above.

### SUMMARY OF THE INVENTION

A method for fabricating a vibrator with a vibrating plate and an electrode for vibrating the vibrating plate. The method includes: laminating a first sacrifice film including silicon and oxygen, a conductive film including silicon, and a second sacrifice film including silicon and oxygen on a base substrate from a lower side in this order; forming a through hole that passes through the conductive film and the second sacrifice film and reaches at least a middle portion in a film thickness direction of the first sacrifice film; filling in an auxiliary film for adjusting temperature characteristics including silicon and oxygen from a lower end position to an upper end position of the through hole; patterning a resist on the conductive film and the second sacrifice film so as to have a shape of the vibrating plate in plan view; subsequently laminating a third sacrifice film including silicon and oxygen and a conductive film for forming an electrode on an upper layer side of the second sacrifice film from the lower side in this order, and patterning a resist on the conductive film for forming an electrode so as to form an electrode in a region outside a vibrating plate; and subsequently etching an upper end portion of the auxiliary film, a lower end portion of the auxiliary film, the first sacrifice film, the second sacrifice film, and the third sacrifice film, while leaving the auxiliary film inside the through hole on the vibrating plate, with a use of an etching fluid including hydrogen fluoride.

### BRIEF DESCRIPTION OF THE DRAWINGS

The foregoing and additional features and characteristics of this disclosure-will become more apparent from the following detailed description considered with reference to the accompanying drawings, wherein:

FIG. 1 is a perspective view illustrating an exemplary vibrator according to the disclosure;

FIG. 2 is a plan view illustrating the vibrator;

FIG. 3 is a vertical cross-sectional view illustrating the vibrator;

FIG. 4 is an enlarged perspective view illustrating a supporting portion for the vibrator;

FIG. 5 is an enlarged vertical cross-sectional view illustrating a part of the vibrator;

FIG. 6 is a perspective view illustrating a method for fabricating the vibrator;

FIG. 7 is a perspective view illustrating a method for fabricating the vibrator;

FIG. 8 is a perspective view illustrating a method for fabricating the vibrator;

FIG. 9 is a vertical cross-sectional view illustrating a method for fabricating the vibrator;

FIG. 10 is a vertical cross-sectional view illustrating the method for fabricating the vibrator;

FIG. 11 is a vertical cross-sectional view illustrating the method for fabricating the vibrator;

FIG. 12 is a vertical cross-sectional view illustrating the method for fabricating the vibrator;

FIG. 13 is a vertical cross-sectional view illustrating the method for fabricating the vibrator;

FIG. 14 is a perspective view illustrating the method for fabricating the vibrator;

FIG. 15 is a vertical cross-sectional view illustrating the method for fabricating the vibrator;

FIG. 16 is a vertical cross-sectional view illustrating the method for fabricating the vibrator;

FIG. 17 is a vertical cross-sectional view illustrating the method for fabricating the vibrator;

FIG. 18 is a vertical cross-sectional view illustrating the method for fabricating the vibrator;

FIG. 19 is a characteristic diagram illustrating an experimental result obtained in the disclosure;

FIG. 20 is a characteristic diagram illustrating an experimental result obtained in the disclosure;

FIG. 21 is a plan view illustrating another example of the vibrator;

FIG. 22 is a plan view illustrating yet another example of the vibrator;

FIG. 23 is a plan view illustrating yet another example of the vibrator;

FIG. 24 is a plan view illustrating yet another example of the vibrator;

FIG. 25 is a plan view illustrating yet another example of the vibrator; and

FIG. 26 is a perspective view illustrating yet another example of the vibrator.

### DETAILED DESCRIPTION

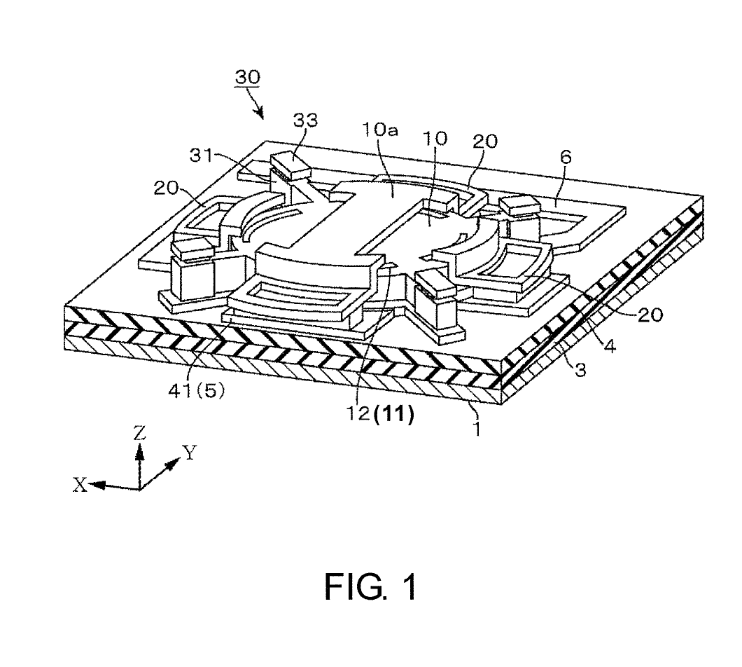

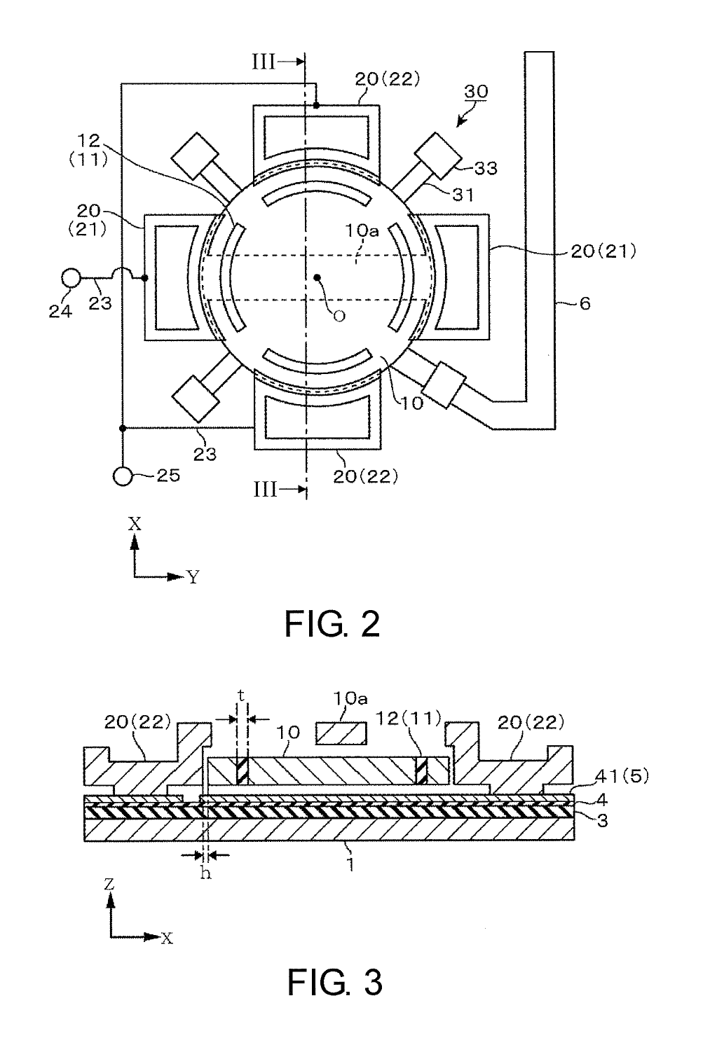

A description will be given for an exemplary embodiment of a method for fabricating a vibrator according to the disclosure with reference to FIG. 1 to FIG. 18. Briefly describing a configuration of the vibrator first, this vibrator includes a disc (circular plate)-shaped vibrating plate 10 and a plurality of, for example, four electrodes 20, which are disposed along a circumferential direction of the vibrating plate 10, As illustrated in FIG. 1 to FIG. 3. This vibrator is configured to transmit and receive a signal between the vibrating plate 10 and the electrodes 20 via an electrostatic bond. This vibrator is configured to obtain a satisfactory frequency versus temperature characteristic while disposing the vibrating plate 10 and the electrodes 20 closely to each other so that an electrostatic bond may easily occur. Subsequently, a description will be given of a specific overview of this vibrator. Reference numerical 1 in FIG. 1 denotes a base substrate, reference numerical 3 denotes a silicon oxide (Si—O) film, and reference numerical 4 denotes a silicon nitride (Si—N) film. FIG. 3 illustrates a vibrator taken vertically along the line III-III in FIG. 2.

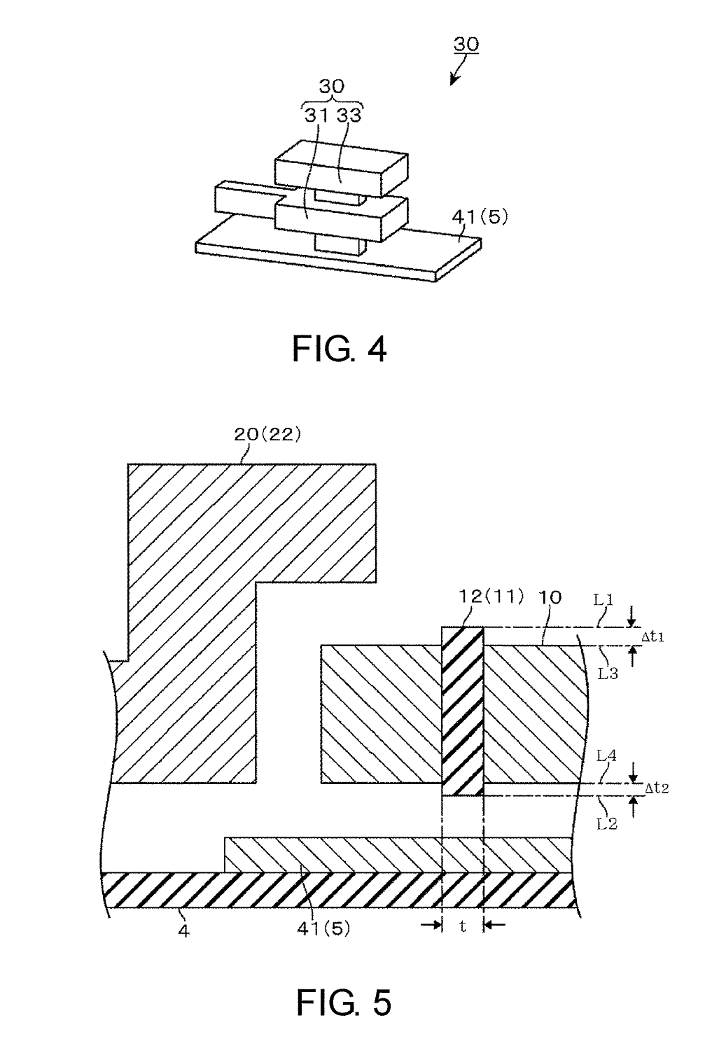

On an outer periphery side of the vibrating plate 10, supporting portions 30 for supporting the vibrating plate 10 are disposed. The supporting portions 30 support the vibrating plate 10 in a state where the vibrating plate 10 floats above the base substrate 1 (specifically, a first polysilicon film 41, which will be described below). These supporting portions 30 are each disposed between the electrodes 20 and 20 adjacent to each other. As illustrated in FIG. 4, each of the supporting portions 30 includes a supporting joist 31 and a support pillar 33. The supporting joist 31 extends horizontally from an outer peripheral surface of the vibrating plate 10 toward an outer periphery side, and the support pillar 33 is disposed to pass vertically through and fit a distal end of this supporting joist 31.

Between: the vibrating plate 10, the supporting portions 30, and the electrodes 20; and the silicon nitride film 4, a conductive film 5 is formed. The conductive film 5 is patterned to correspond to shapes of the vibrating plate 10, the electrodes 20, and the supporting portions 30. Each of the supporting portions 30 is supported by the conductive film 5. Each of the electrodes 20 is also supported by the conductive film 5. As illustrated in FIGS. 1 and 2, one end of an extraction electrode 6 is connected to the conductive film 5 positioned on a lower side of one of the four supporting portions 30. The extraction electrode 6 extends toward the outer periphery side. The other end of this extraction electrode 6 serves as a port through which a DC bias voltage is applied to the vibrating plate 10 at the time of vibrating the vibrating plate 10.

A beam portion 10a is disposed on an upward side of the vibrating plate 10. The beam portion 10a connects two electrodes 20 and 20, which face each other, of the four electrodes 20. FIG. 2 illustrates the beam portion 10a in a one dot chain line with a part of the beam portion 10a notched. Reference numerals 24 and 25 in FIG. 2 respectively denote an input port and an output port, and reference numeral 23 denotes a conductive path. Among the four electrodes 20, reference numeral “21” may be assigned to an electrode 20 connected to the input port 24, and reference numeral “22” may be assigned to an electrode 20 connected to the output port 25.

The vibrating plate 10 is formed to be disc-shaped, and is constituted by a conductive film that is made up of polysilicon (specifically, a polysilicon compound doped with impurities such as phosphorus). As illustrated in FIG. 1 to FIG. 3, a through hole 11, which vertically passes through the vibrating plate 10, is formed at each of a plurality of, for example, four points on the vibrating plate 10. An auxiliary film 12, which is made up of silicon and oxygen, for adjusting temperature characteristics is filled in each of the through holes 11. Specifically, each of the auxiliary films 12 (through holes 11) is formed in an arc-shape so as to run along an outer edge of the vibrating plate 10 in plan view, and is disposed to be equally spaced apart from each other along a circumferential direction of the vibrating plate 10, as illustrated in FIG. 2.

In this example, each of the auxiliary films 12 is disposed to avoid a region between a center point O of the vibrating plate 10 and each of the supporting portions 30, that is, so as to face each of the electrodes 20. The center point O serves as a center in plan view. As illustrated in FIG. 3, a width dimension t of the auxiliary film 12 in a radius direction of the vibrating plate 10 is, for example, 0.5 μm to 2.0 μm. The reason why the width dimension t is set to such a range will be described later.

Here a height position of a top surface of the vibrating plate 10 and a height position of a top surface of each of the auxiliary films 12 are aligned with each other. A height position of a bottom surface of the vibrating plate 10 and a height position of a bottom surface of each of the auxiliary films 12 are also aligned with each other. The “Being aligned” here refers specifically to the following range; the height levels of the top surface and the bottom surface of the auxiliary film 12 when, for example, viewed from a side of the base substrate 1, are respectively denoted by “L1” and “L2”, as illustrated in FIG. 5. Similarly, the height levels of the top surface and the bottom surface of the vibrating plate 10 when viewed from a side of the base substrate 1 are respectively denoted by “L3” and “L4”.

With regard to a difference between the height levels L1 and L3, or Δt1 (L1−L3), the “being aligned” means that Δt1 is equal to or less than one third of a thickness dimension of the vibrating plate 10. Similarly with regard to a difference between the height levels L2 and L4, or Δt2 (L4−L2), “being aligned” means that Δt2 is equal to or less than one third of the thickness dimension of the vibrating plate 10. Note that the above-described FIG. 5 illustrates the upper and lower ends of the auxiliary film 12 as protruding well from the top and bottom surfaces of the vibrating plate 10 in order to describe the definitions of the differences Δt1 and Δt2.

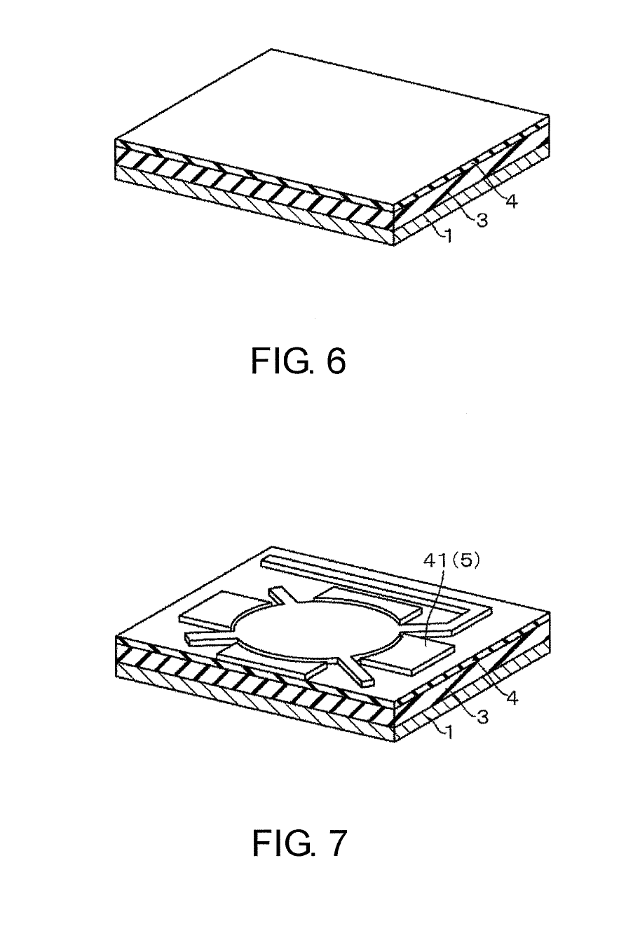

A method of forming an auxiliary film 12 with such a shape will be described below with reference to FIG. 6 to FIG. 18. To begin with, as illustrated in FIG. 6, a silicon oxide film 3 and a silicon nitride film 4 on a base substrate 1 are laminated in this order using, for example, a Chemical Vapor Deposition (CVD) method.

Subsequently, the first polysilicon film 41, which is made up of polycrystalline silicon, is formed on an upper layer side of the silicon nitride film 4 and phosphorus is diffused into the first polysilicon film 41. Then, a resist pattern is formed on the first polysilicon film 41 by the photolithography method so as to correspond to shapes of the vibrating plate 10, the supporting portion 30, the electrode 20, and the extraction electrode 6, as illustrated in FIG. 7. The first polysilicon film 41 serves as the above-described conductive film 5. This embodiment describes one of many vibrators formed longitudinally and laterally on the base substrate 1.

Subsequently, a first sacrifice film 61, a second polysilicon film 42 made up of polycrystalline silicon (specifically, a conductive film doped with phosphorus after forming a polycrystalline silicon film), and a second sacrifice film 62 on the upper layer side of the first polysilicon film 41 are laminated from the lower side in this order using, for example, the CVD method. The sacrifice films 61 and 62 are silicon oxide films containing impurities such as phosphorus or boron, in addition to silicon and oxygen. This means that these sacrifice films 61 and 62 are thin films doped with the impurities at the time of formation of a silicon oxide film in the CVD method. The film thickness dimension of each of the sacrifice film 61 and 62 is, for example, 1 μm. The sacrifice films 61 and 62 may be subject to an annealing process after being doped with impurities.

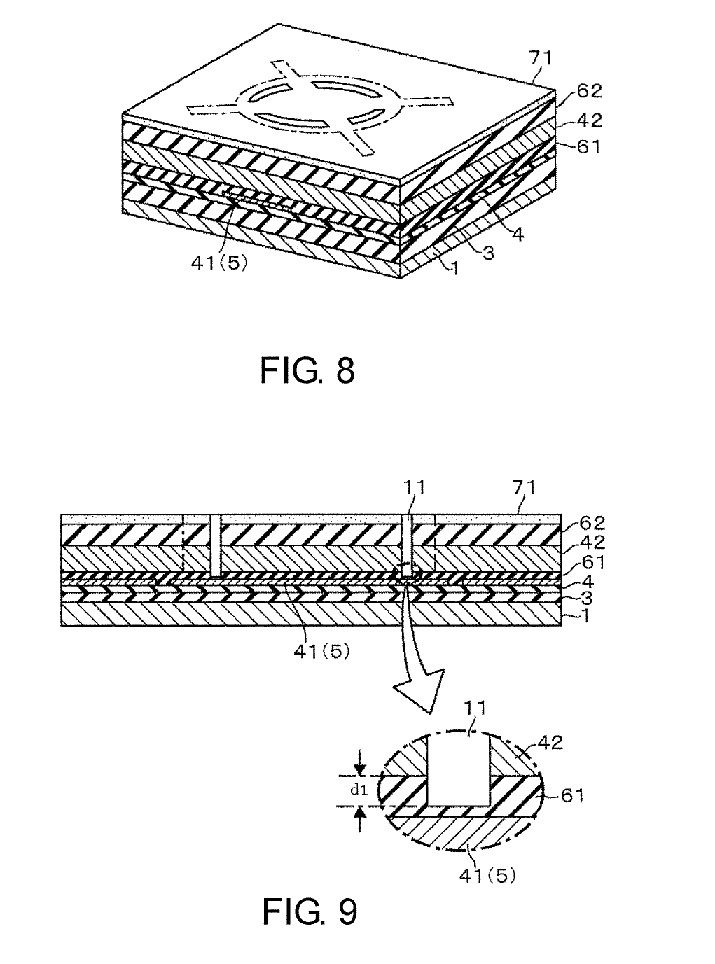

Subsequently, a photoresist mask 71 is formed on an upper layer side of the second sacrifice film 62, and a resist pattern corresponding to the through hole 11 is formed on the photoresist mask 71, as illustrated in FIG. 8. Then, as illustrated in FIG. 9, the through hole 11 is formed in the second sacrifice film 62, the second polysilicon film 42, and the first sacrifice film 61 through the photoresist mask 71 while using different kinds of etching gas. The through hole 11 is formed in a film thickness direction to reach a middle portion of the first sacrifice film 61, as illustrated in an enlarged scale at a lower part of FIG. 9. As an example of a depth position of the through hole 11, a dimension d1 between a top surface (a bottom surface of the second polysilicon film 42) of the first sacrifice film 61 and a bottom surface of the through hole 11 is, for example, 0 μm to 1.0 μm. In FIG. 8, a region where the vibrating plate 10 and the supporting portion 30 is formed is depicted by a one dot chain line.

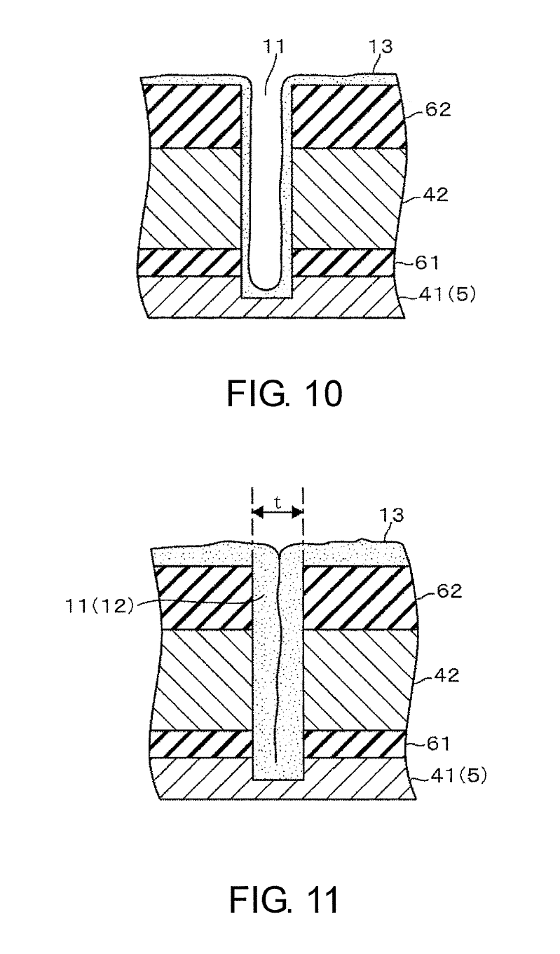

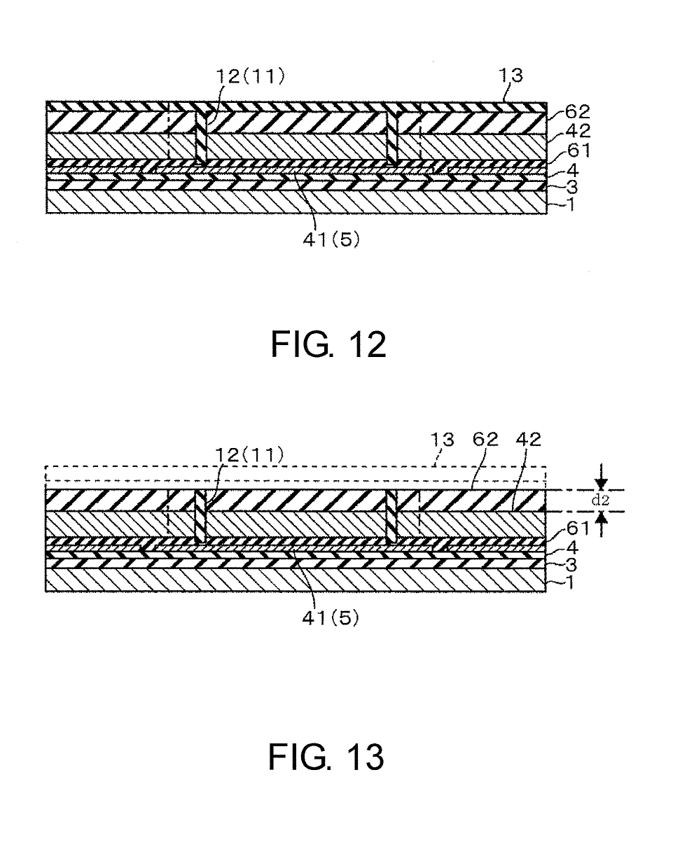

After the photoresist mask 71 is removed, a thin film 13, which is made up of an silicon oxide film, is formed on a surface of the second sacrifice film 62, which includes an inside of the through hole 11, by the CVD method. Specifically, an organic processing gas, which contains silicon, and an oxidizing gas for oxidizing the processing gas are supplied onto the surface of the second sacrifice film 62. The processing gas and the oxidizing gas come into contact with exposed surfaces of the second sacrifice film 62 and similar, whereby, as illustrated in FIG. 10, the thin film 13 is formed along the inner wall surface and the bottom surface of the through hole 11 and the surface of the second sacrifice film 62. Continuing to form the thin film 13 will increase the thickness of the thin film 13, which in turn reduces an opening area of the through hole 11, as illustrated in FIG. 11. The through hole 11 is thus filled by the thin film 13 and an auxiliary film 12 is formed. As illustrated in FIG. 12 as well, the thin film 13 is formed on the surface of the second sacrifice film 62. The thin film 13 has a film thickness dimension of, for example, 1 μm.

Subsequently, as illustrated in FIG. 13, a full etch back is conducted by removing a redundant thin film 13, which has been formed on the surface of the second sacrifice film 62, and an upper layer portion of the second sacrifice film 62 through dry etching. Specifically, the thin film 13 is etched with the use of etching gas for a silicon oxide film (for example, C-F gas) to expose the second sacrifice film 62. Then, the second sacrifice film 62 is etched on the same condition until the remaining film of the second sacrifice film 62 becomes to have a film thickness dimension d2. In the dry etching process, the difference in etching rate between the second sacrifice film 62 and the thin film 13 is small. As a result, the top end surface of the second sacrifice film 62 and the top end surface of the thin film 13 will be almost flat. A laminate, as illustrated in the above-described FIG. 13, can be thus obtained. As a method for a full etch back, the top end surface of the second sacrifice film 62 and the top end surface of the thin film 13 may be aligned with each other by Chemical Mechanical Policing (CMP), instead of dry etching.

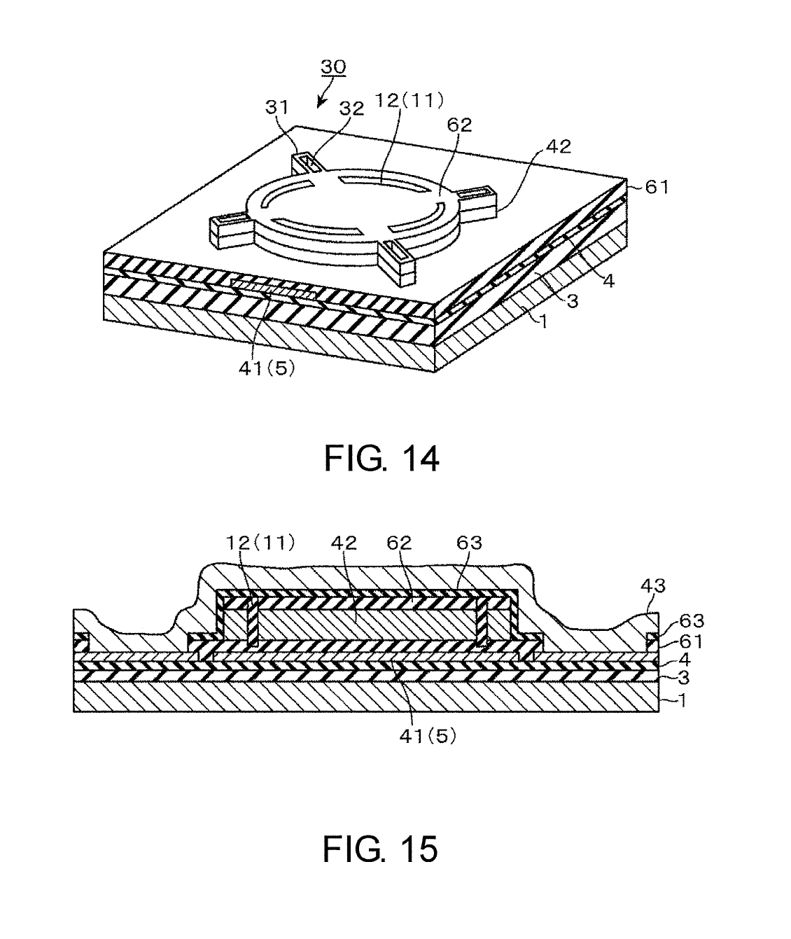

After the above-described etching process, the film thickness dimension d2 of the second sacrifice film 62 will be, for example, 0 μm to 1.0 μm. In other words, the auxiliary film 12 will protrude from the top surface of the second polysilicon film 42 by the film thickness dimensions d2. Then, as illustrated in FIG. 14, a resist pattern is formed on the second sacrifice film 62 and the second polysilicon film 42 so as to correspond to the shapes of the vibrating plate 10 and the supporting portion 30. Reference numeral 32 in FIG. 14 denotes an opening at a distal end of the supporting joist 31 through which the support pillar 33 is inserted. In FIG. 12 and FIG. 13, the film thickness dimension d2 of the second sacrifice film 62 are exaggerated.

Subsequently, a third sacrifice film 63 is formed so as to cover the structure formed in the above processes. The third sacrifice film 63 is made up of silicon oxide and the structure is made up of the second sacrifice film 62 and the second polysilicon film 42. The third sacrifice film 63 is formed so as to have the same film thickness dimension as a clearance dimension between the vibrating plate 10 and the electrode 20. The third sacrifice film 63 may be a silicon oxide film containing impurities but does not need to contain impurities because this film has a small film thickness dimension. In a wet etching process conducted after a vibrator is formed, the sacrifice films 61 to 63 are made to be easier to be etched compared with the thin film 13, as described below. Specifically, the sacrifice films 61 and 62 are doped with impurities. In contrast, the third sacrifice film 63 is etched quickly even if it is not doped with impurities and is etched even more quickly if doped with impurities, because the film has a small film thickness dimension, as described above. Then, a resist pattern is formed on the sacrifice films 61 and 63 such that the conductive film 5 (the first polysilicon film 41) on a lower side of the opening 32 and on a lower side of the electrode 20 will be exposed.

As illustrated in FIG. 15, a third polysilicon film 43 is formed as a conductive film for forming an electrode so as to cover the structure formed on the base substrate 1 in the above processes, and then the third polysilicon film 43 is doped with phosphorus. The third polysilicon film 43 is made up of polycrystalline silicon. The third polysilicon film 43 is formed so as to run along an exposed surface such as an internal region of the above-described opening 32. As a result, the conductive film 5 on the lower side of the third polysilicon film 43 and the opening 32 and the conductive film 5 on the lower side of the electrode 20 come into contact (electrically conducted) with each other, and the third polysilicon film 43 and the vibrating plate 10 (the second polysilicon film 42) also come into contact with each other via an inner wall surface of the opening 32. The third polysilicon film 43 that faces a side peripheral surface of the vibrating plate 10 is spaced away from the side peripheral surface by the film thickness dimension of the third sacrifice film 63.

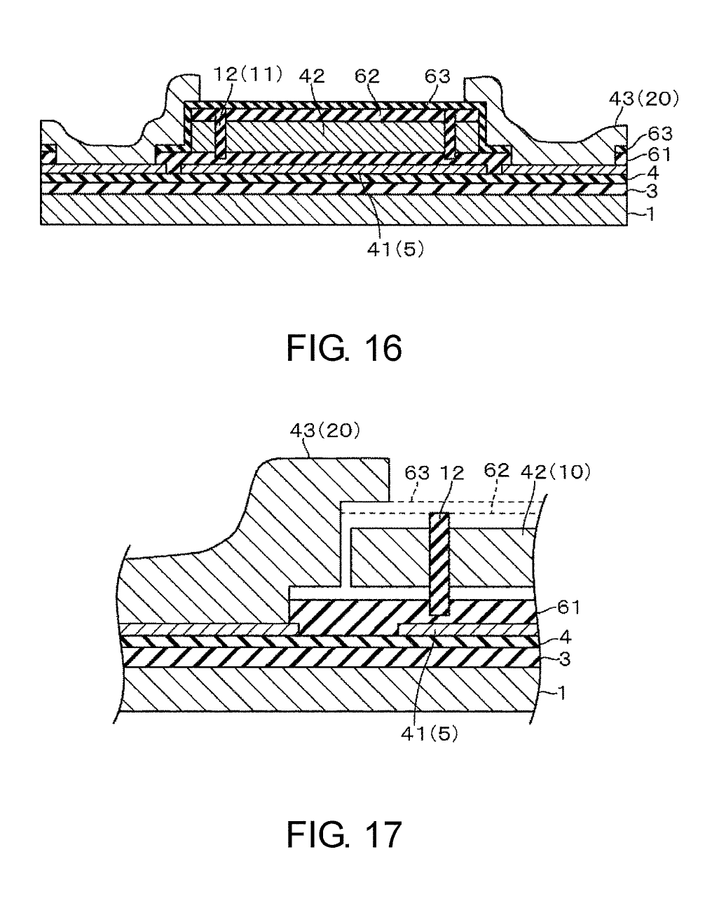

Then, a resist film (not shown) having an opening in a region other than the regions for the electrode 20, the support pillar 33, and the beam portion 10a is formed, the third polysilicon film 43 is dry etched as illustrated in FIG. 16. Dipping the structure formed on base substrate 1 together with the base substrate 1 into an etchant (etching fluid) such as a hydrogen fluoride water solution will meander this etchant into a lower side of the third polysilicon film 43 or a peripheral area of the supporting joist 31.

The sacrifice films 61 and 62 are silicon oxide films (phosphorus-doped silicate glass: PSG) containing impurities such as phosphorus, as described above, and easily dissolve in the etchant, as illustrated in later-described FIG. 19. The third sacrifice film 63 also dissolves in etchant easily if it contains impurities. Even if the third sacrifice film 63 does not contain impurities, it is quickly etched because the film has a small film thickness dimension, as described above. On the other hand, the auxiliary film 12 is a silicon oxide film (non-doped silicate glass: NSG) made up of silicon and oxygen and does not contain such impurities. As seen from FIG. 19, the dissolution speed (the etching rate) in the etchant is hence equal to or less than, for example, approximately 1/40, compared with the dissolution speed of the sacrifice films 61 and 62. “BSG” in FIG. 19 represents a silicon oxide film doped with boron (boron-doped silicate glass). FIG. 19 also illustrates that, among the two “PSG” data, the right side data contains more phosphorus than the left side data.

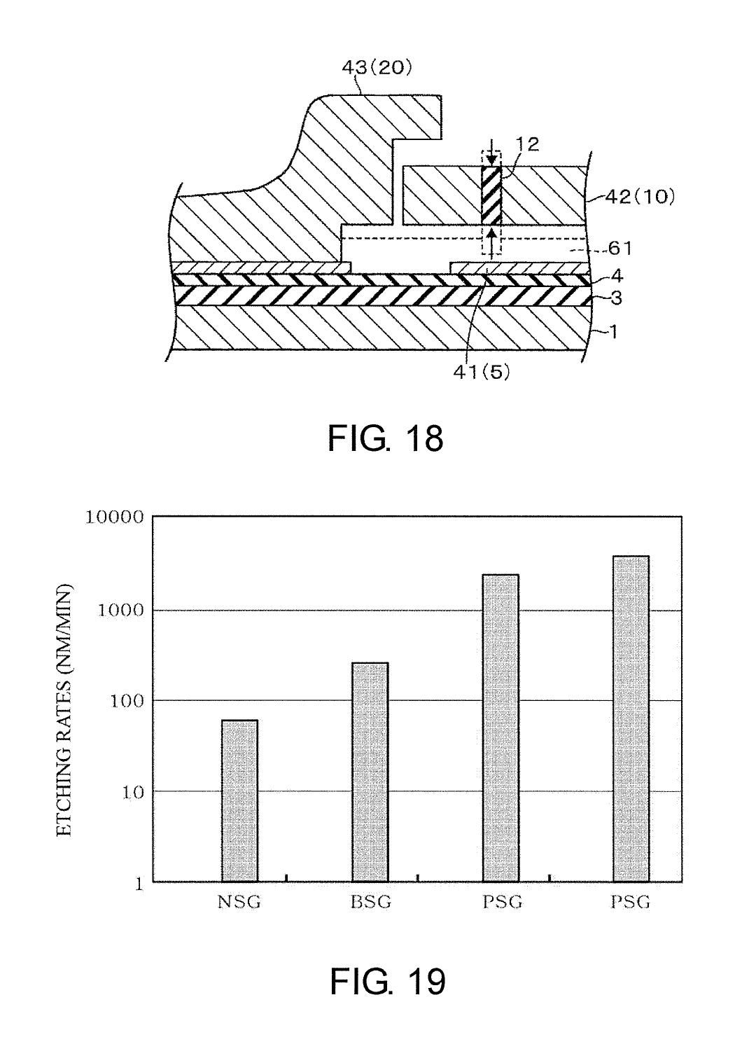

Therefore, the sacrifice films 62 and 63 are etched more quickly than the auxiliary film 12 in an upper region of the vibrating plate 10, for example, when the structure is dipped in an etchant, as illustrated in FIG. 17. In a lower region of the vibrating plate 10 as well, the sacrifice films 61 to 63 are more preferentially etched than the auxiliary film 12. While the sacrifice films 61 to 63 are etched, the upper and lower ends of the auxiliary film 12, which protrude from the vibrating plate 10 upward and downward, are etched, and the top and bottom surfaces of the vibrating plate 10 and the top and bottom surfaces of the auxiliary film 12 are aligned with each other, as illustrated in FIG. 18.

In other words, in this disclosure, the period required to wet etch the sacrifice films 61 to 63 is obtained in advance through, for example, an experiment, and the dimensions d1 and d2 are each set such that the upper and lower ends of the auxiliary films 12 will be removed during this etching period. As a result, the above wet etching process removes the sacrifice films 61 to 63 and forms a vibrator, as illustrated in the above-described FIG. 1 to FIG. 3.

An example of specific dimensions d1 and d2 will be described below. Assume that a vibrating plate 10 with a radius dimension of 30 μm is to be formed, and compounds whose etching rates in a hydrogen fluoride water solution have the values listed in the following table will be used as the respective sacrifice films 61 to 63. The following table also illustrates the etching rate of the compound used as the auxiliary film 12. Note that these etching rates are merely exemplary and vary depending on, for example, the amount of impurities or the state of an annealing process (heat treatment) and the concentration or composition of the hydrogen fluoride water solution to be used.

| | TABLE |
|---|---|
| | Etching rates (nm/min) |
| First sacrifice film (PSG) | 2600 |
| Second sacrifice film (PSG) | 2600 |
| Third sacrifice film (BSG) | 250 |
| Auxiliary film (NSG) | 60 |

This example shows that removing (wet etching) the first sacrifice film 61 having the above-described film thickness dimension (1 μm) takes 12.5 minutes. Thirteen minutes, including a margin, will be accordingly assigned to remove each of the sacrifice film 61 to 63. From the fact that the auxiliary film 12 is etched 780 nm in 13 minutes, it can be seen that the above-described dimensions d1 and d2 may well be both set to 780 nm.

Going through the above-described film formation process and etching (dry etching and wet etching) process spaces the vibrating plate 10 and the electrode 20 apart from each other by the film thickness dimension of the third sacrifice film 63 (for example, 0.01 to 1.0 μm, 0.1 μm in this example). The vibrating plate 10 is supported via the supporting portion 30 in a state where the vibrating plate 10 floats above the first polysilicon film 41. The beam portion 10a is put into a state where the beam portion 10a floats above the vibrating plate 10 by the film thicknesses of the second sacrifice film 62 and the third sacrifice film 63. Then, performing a sealing process and cutting the base substrate 1 along a dicing line that partitions the vibrator separates each vibrator into individual pieces.

For this vibrator, an oscillation frequency of the vibrating plate 10 hardly vary even if the temperature of the atmosphere where the vibrator is placed changes while an output signal is being output. In other words, as already described in the background paragraph, silicon and silicon oxide have a frequency versus temperature characteristic that cancel each other. The auxiliary film 12, which is made up of silicon oxide, is filled in the vibrating plate 10, which is made up of silicon, as described earlier. As a result, the oscillation frequency of the auxiliary film 12 will decrease even if the oscillation frequency of the vibrating plate 10 attempts to increase according to a change in temperature outside the vibrator. On the other hand, the oscillation frequency of the auxiliary film 12 will increase even if the oscillation frequency of the vibrating plate 10 attempts to decrease. The constitution made up of the vibrating plate 10 and the auxiliary film 12 hence provides an almost constant value of oscillation frequency regardless of a change in outside temperature.

According to the aforementioned embodiment, the vibrating plate 10 is formed from silicon (polycrystalline silicon) with the use of the sacrifice films 61 to 63 as a silicon oxide film. At the time of formation of the vibrating plate 10, the through hole 11 is provided in the vibrating plate 10, and the auxiliary film 12, which is made up of silicon and oxygen, is filled in the through hole 11. The auxiliary films 12 are each made to protrude upward and downward in advance from the top and bottom surfaces of the vibrating plate 10, respectively, assuming that a thickness of the auxiliary film 12 will be reduced when the sacrifice films 61 to 63 are wet etched. Hence the top and bottom surfaces of the vibrating plate 10 and the top and bottom surfaces of the auxiliary film 12 can be aligned with one another when the sacrifice films 61 to 63 have been etched. In other words, unless the auxiliary film 12 is made to protrude from the vibrating plate 10 upward and downward, the auxiliary film 12 will be immersed from both of the upper and lower sides in the subsequent wet etching process. As a result, the auxiliary film 12 will not remain in the through hole 11 or leave the effect of correcting the temperature characteristics insufficient even if the auxiliary film 12 remains.

On the other hand, having the auxiliary film 12 to protrude from the vibrating plate 10 upward and downward can leave the auxiliary film 12 in the through hole 11 even after the wet etching process. This makes it possible to form the auxiliary film 12 in the course of the process of fabricating the vibrator, and thus eliminating the need for interposing the auxiliary film 12 between the vibrating plate 10 and the electrode 20. As a result, a vibrator having a satisfactory frequency versus temperature characteristic can be obtained by combining the auxiliary film 12, which is made up of silicon oxide film, with the vibrating plate 10, which is made up of silicon, while bringing the vibrating plate 10 and the electrode 20 closer to each other to constitute a low voltage drive type vibrator.

The sacrifice films 61 and 62 are doped with impurities, and the auxiliary film 12 is constituted as a silicon oxide film without being doped with impurities. As can be seen from the above-described FIG. 19, the etching rate of the auxiliary film 12 can be hence reduced compared with the etching rates of the sacrifice films 61 and 62. This eliminates the need for setting the dimensions d1 and d2, which are the dimensions that protrude from the vibrating plate 10 upward and downward, to be large. Accordingly, there is no need for thickening the sacrifice film 61 and 62, which are positioned on and beneath the vibrating plate 10. This allows an etching process on the sacrifice film 61 and 62 to progress quickly, resulting in an improvement in the throughput of vibrators. As can be seen from FIG. 19, phosphorus is preferred as impurities with which to dope the sacrifice films 61 and 62, compared with boron. However, both of phosphorus and boron may be doped because the doping process is intended to make a significant difference in etching rate between the sacrifice films 61 and 62 and auxiliary film 12. The sacrifice films 61 and 62 may be doped with alkali or metal oxide as impurities instead of or together with phosphorus or boron. Specifically, examples of alkali or metal oxide include Na₂O (sodium oxide), K₂O (potassium oxide), and CaO (calcium oxide).

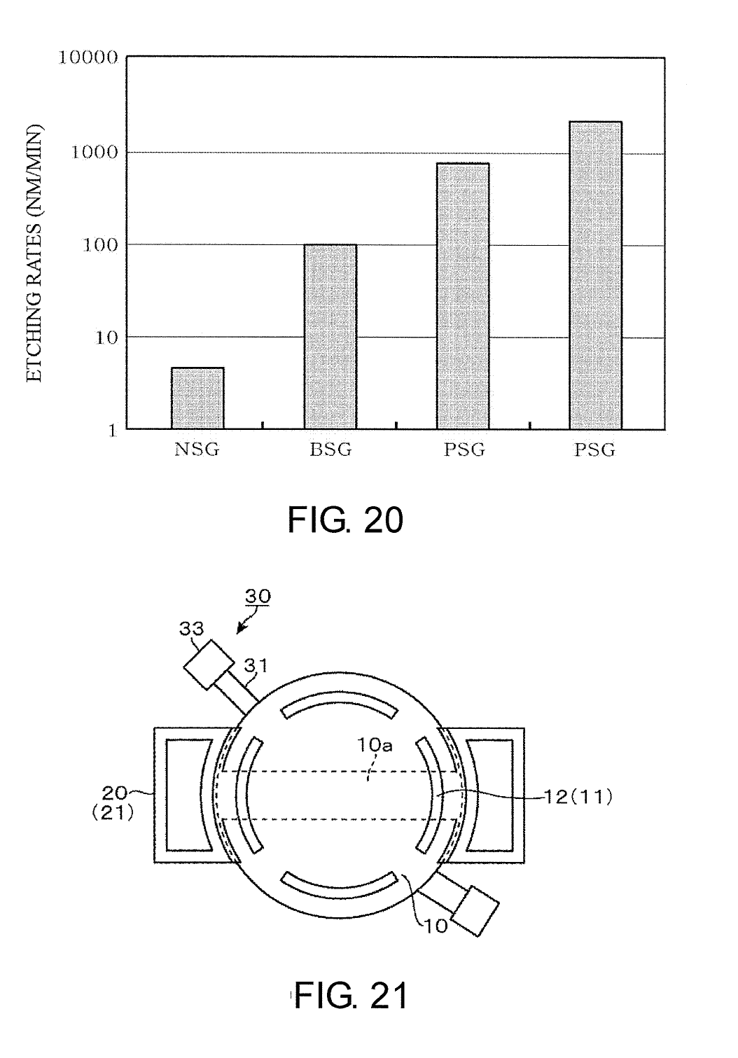

As illustrated in FIG. 20, use of an HF-based etchant containing a component other than the above-described examples can further increase the selection rate (etching rate ratio) of PSG (the sacrifice films 61 and 62) and NSG (the auxiliary film 12). Hence, the disclosure can be applied to a device having a resonator with a different dimension or design by selecting an optimum combination of a dopant (impurities) and an etchant with which to dope the sacrifice film 61 and 62. Among the two “PSG” data shown in FIG. 20, the right data contains more phosphorus than the left data.

Now, a description will be given for the reason why the width dimension t of the auxiliary film 12 has been set within the above-described range. The auxiliary film 12 needs to have a smaller solubility in hydrogen fluoride than the sacrifice films 61 and 62. Hence, at the time of formation of the auxiliary film 12, it is preferred that the auxiliary film 12 not only be free of impurities such as phosphorus but also be formed into a fine film.

As described in the above-described FIGS. 10 and 11, the CVD method gradually increases the thickness of the thin film 13 on the inner wall surface of the through hole 11 and thus filling the inside of the through hole 11 with the thin film 13. If the width dimension t of the auxiliary film 12 (the opening area of the through hole 11) is too large, the formed film amount and the etched amount will concurrently become large, possibly resulting in poor uniformity in film thickness. In contrast, if the width dimension t is too small, the effect of correcting temperature characteristics may not be fully achieved by the oxidized film. Therefore, the width dimension t should be preferably set within the above-described range.

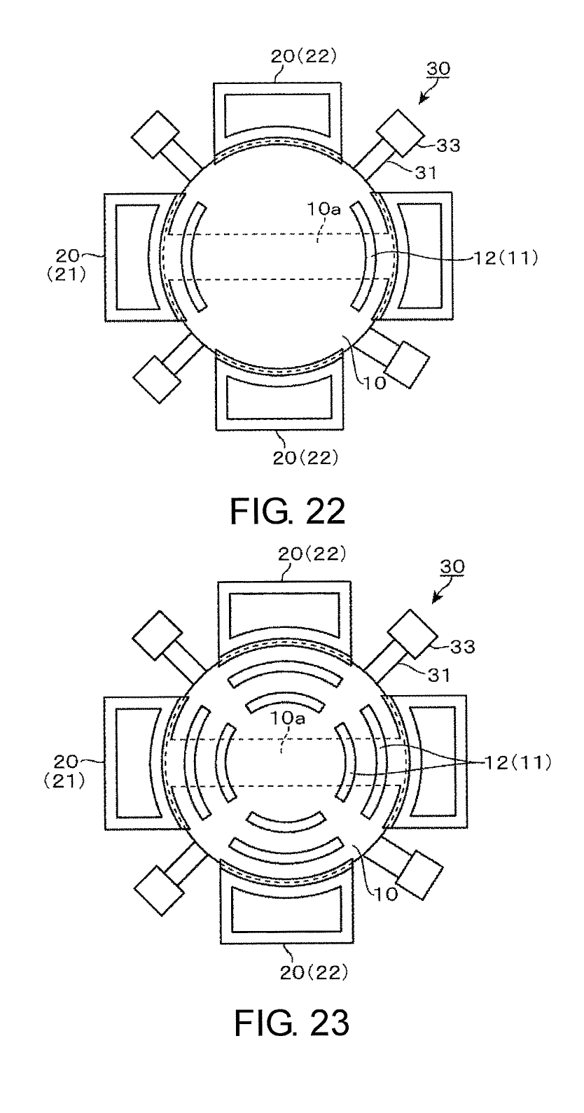

Other examples of the vibrator described above will be listed below. FIG. 21 illustrates an example where two supporting portions 30 and two electrodes 20 are disposed. Specifically, the supporting portions 30 and the electrodes 20 are each disposed to face each other via the vibrating plate 10. FIG. 22 illustrates an example where an auxiliary film 12 (through hole 11) is disposed at two positions. These auxiliary films 12 are formed in arc-shape so as to run along an outer peripheral edge of the vibrating plate 10 similarly to the configuration in the above-described FIG. 2, and are disposed at positions that face the respective electrodes 21 and 21 among the four electrodes 20. In FIG. 22, four supporting portions 30 and four electrodes 20 are disposed. The same applies to FIGS. 23 to 25.

FIG. 23 illustrates an example where auxiliary films 12 are additionally disposed further inside the position of the auxiliary films 12 illustrated in the above-described FIG. 2. Specifically, the auxiliary films 12 are disposed at four points along a circle centered on a center position O of the vibrating plate 10 as well as formed at positions near to the outer edge of the vibrating plate 10. The auxiliary films 12 are disposed at four points along a circle nearer to the center position O than this circle (having a smaller radius) as well. Each of the auxiliary films 12 is disposed at a position where to face each of the electrodes 20.

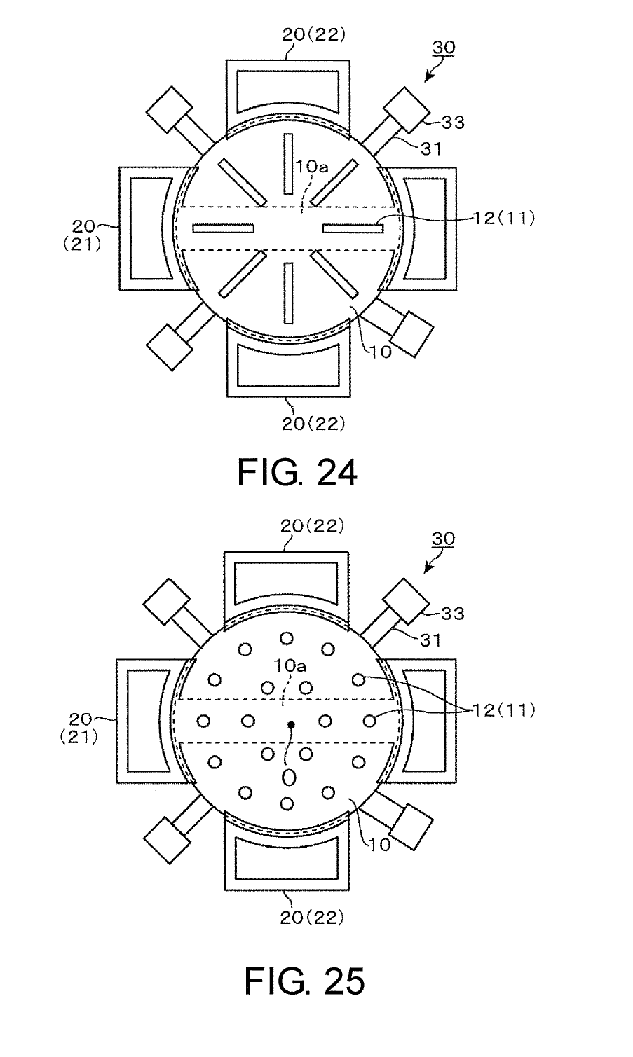

FIG. 24 illustrates an example where auxiliary films 12 are disposed radially at a plurality of points along a radius direction of the vibrating plate 10 instead of being formed along an outer peripheral edge of the vibrating plate 10. In this example, the auxiliary films 12 are disposed at, for example, eight points at regular intervals in a circumferential direction of the vibrating plate 10.

FIG. 25 illustrates an example where auxiliary films 12 are formed in a dot (hole) pattern, instead of being linearly formed. In this example, the auxiliary films 12 are disposed at twelve points along a circle that is centered on the center position O of the vibrating plate 10 and is near the outer edge of the vibrating plate 10. Also in this example, the auxilliary films 12 is disposed at six points along a circle inner to the circle that is near the outer edge of the vibrating plate 10. A width dimension t of the auxiliary film 12 (a dimension of an opening of the hole) is set in the approximately same amount as illustrated in the above-described example.

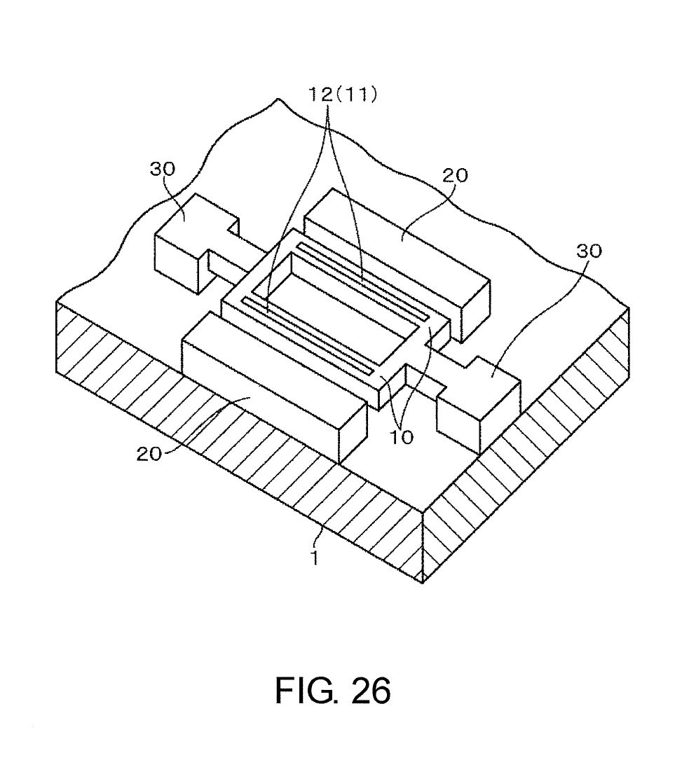

FIG. 26 illustrates an example where the vibrating plate 10 is formed like a double-ended tuning fork, instead of being formed in a disc shape. Specifically, a pair of supporting portions 30 and 30 are disposed on the base substrate 1 to be in opposite sides of each other. A pair of vibrating plates 10 and 10, which each prismatically extends so as to connect the supporting portion 30 and 30, is formed between the supporting portion 30 and 30. The vibrating plates 10 and 10 are each supported at both ends by the supporting portions 30 and 30 so as to be parallel to each other. In plan view, the vibrating plates 10 and 10 have a width dimension, for example, approximately 6 μm each of vibrating plates 10, an auxiliary film 12 (through hole 11) is formed in a lengthwise direction of the vibrating plate 10. Assuming that a direction in which the vibrating plate 10 extends is referred to as a longitudinal direction, an electrode 20 is disposed both on the right and left to the region where these vibrating plates 10 and 10 are disposed.

For such a vibrator, supplying an input signal to the electrodes 20 and 20 causes each vibrating plate 10 to generate flexure vibrations. Specifically, the vibrating plates 10 and 10 generate vibrations between a position where the vibrating plates 10 and 10 come close to each other and a position where the vibrating plates 10 and 10 separate away from each other. In FIG. 26, a film structure near the base substrate 1 on a lower side of the supporting portions 30 or the vibrator is simplified.

For a vibrator including the vibrating plate 10 having a small width dimension like this, the sacrifice films 61 to 63 each have a relatively small area in plan view. Consequently, it takes only a short time for a wet etching process. If hydrogen fluoride diluted with water is used, the film amount to be reduced (dimensions d1 and d2) of the auxiliary film 12 will be equal to or less than 80 nm.

Now a preferred range of the above-described differences Δt1 and Δt2 after a vibrator is fabricated (wet etched) will be described. Specifically, if the differences Δt1 and Δt2 both have a negative value, that is, an upper end portion or a lower end portion of an auxiliary film 12 intrudes into the vibrating plate 10, as can be seen from the above-described description, the auxiliary film 12 provides lower capability of adjusting temperature characteristics and could also possibly provide unstable vertical vibration. Hence, the differences Δt1 and Δt2 should preferably have zero or a positive value. In contrast, if the auxiliary film 12 protrudes above and below excessively from the vibrating plate 10 after the vibrator is fabricated, that is, the differences Δt1 and Δt2 both have a large positive value, vibrations of the vibrating plate 10 may be possibly hindered. Summarizing the above, the differences Δt1 and Δt2 should preferably fall within the following range: 0 μm≦Δt1(Δt2)≦(one-third of the thickness dimension of the vibrating plate 10).

As can be also seen from the above-described FIG. 9, at the time of formation of the through hole 11, the through hole 11 may be formed to be deep until the first polysilicon film 41 is exposed, depending on a film thickness dimension of the first sacrifice film 61.

In the above-described FIG. 13, the second sacrifice film 62 is also etched, as well as the thin film 13 formed on the upper side of the second sacrifice film 62, when the dimension d2 of the auxiliary film 12, which protrudes upward from the vibrating plate 10, is set. However, the film thickness dimension of the second sacrifice film 62 may be adjusted to the dimension d2 in advance. In this case, only the thin film 13 on the upper side of the second sacrifice film 62 may be etched, in the process shown in FIG. 13. Alternatively, the region on the second sacrifice film 62 side (lower-layer side) of the thin film 13 may be left unetched to be removed when the respective sacrifice films 61 to 63 are wet etched.

Again in FIG. 13, the photoresist mask 71 for forming the through hole 11 is removed first when the auxiliary film 12 is filled into the through hole 11. However, the auxiliary film 12 may be filled in before the photoresist mask 71 is removed. In this case, the thin film 13 is formed so as to cover the surface of the photoresist mask 71 along with the inside of the through hole 11. Then, the photoresist mask 71 is removed with the use of an organic flux or an alkali solution. A frame structure, which is made up of the thin film 13, is thus formed above the second sacrifice film 62 in the state where the frame structure floats from the second sacrifice film 62. Mechanically removing the frame structure by lifting it off through a wet etching process will leave the auxiliary film 12 in the through hole 11.

In the method for fabricating a vibrator, a height position of a bottom surface of the through hole may be set at a position downward away from a bottom surface of the vibrating plate by a film thickness dimension to be etched at a lower end portion of the auxiliary film in the etching such that a bottom surface of the vibrating plate and a lower end position of the auxiliary film inside the through hole are aligned with each other after the etching process. In the method for fabricating a vibrator, the second film thickness dimension may be set to have a same dimension as a film thickness dimension to be etched at an upper end portion of the auxiliary film in the etching such that a top surface of the vibrating plate and an upper end position of the auxiliary film inside the through hole are aligned with each other after the etching process.

In the method for fabricating a vibrator, the filling-in may form the auxiliary film inside the through hole and on a surface of the second sacrifice film by supplying a processing gas including silicon and oxidizing gas for oxidizing the processing gas onto a superficial layer side of the second sacrifice film. The method may further include etching an excess of the auxiliary film formed on a surface of the second sacrifice film and an upper layer portion of the second sacrifice film after the filling-in so as to adjust a height dimension of the auxiliary film protruding above an upper end position of the vibrating plate. In the method for fabricating a vibrator, the adjusting the height dimension protrudes the upper end portion of the auxiliary film above the vibrating plate by a film thickness dimension to be etched at the upper end portion of the auxiliary film in the etching process such that the top surface of the vibrating plate and the upper end position of the auxiliary film inside the through hole are aligned with each other after the etching process.

In the method for fabricating a vibrator, the first the sacrifice film, the second sacrifice film, and the third sacrifice film may each include at least one of boron, phosphorus, sodium oxide, potassium oxide and calcium oxide in addition to silicon and oxygen, and the auxiliary film may be a silicon oxide film made up of silicon and oxygen. In the method for fabricating a vibrator, at least one of a composition of the etching fluid and a composition of the first sacrifice film may be set such that an etching speed of the first sacrifice film at a time of usage of the etching fluid becomes 50 times or more of an etching speed of the auxiliary film.

The disclosure forms a vibrating plate, which is made up of a conductive film including silicon, and an electrode for vibrating this vibrating plate using a sacrifice film including silicon and oxygen. In this process, a through hole that passes through in the vertical direction is formed, and an auxiliary film constituted of silicon and oxygen is filled in the through hole. The auxiliary film is made to protrude upward and downward in advance from the top and bottom surfaces of the vibrating plate, assuming that a thickness of the auxiliary film will be reduced when the sacrifice films are etched. This can leave the auxiliary film inside the through hole even after the etching process of the sacrifice films has been completed. This makes it possible to form the auxiliary film in the course of the process of fabricating the vibrator, thus eliminating the need for interposing the auxiliary film between the vibrating plate and the electrode. As a result, a vibrator having a satisfactory frequency versus temperature characteristic can be obtained by combining the auxiliary film, which is made up of silicon oxide film, with the vibrating plate, which is made up of silicon, while bringing the vibrating plate and the electrode close to each other.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A method for fabricating a vibrator with a vibrating plate and an electrode for vibrating the vibrating plate, the method comprising:
laminating a first sacrifice film including silicon and oxygen, a conductive film including silicon, and a second sacrifice film including silicon and oxygen on a base substrate from a lower side in this order;
forming a through hole that passes through the conductive film and the second sacrifice film and reaches at least a middle portion in a film thickness direction of the first sacrifice film;
filling in an auxiliary film for adjusting temperature characteristics including silicon and oxygen from a lower end position to an upper end position of the through hole;
patterning a resist on the conductive film and the second sacrifice film so as to have a shape of the vibrating plate in plan view;
subsequently laminating a third sacrifice film including silicon and oxygen and a conductive film for forming an electrode on an upper layer side of the second sacrifice film from the lower side in this order, and patterning a resist on the conductive film for forming an electrode so as to form an electrode in a region outside a vibrating plate; and
subsequently etching an upper end portion of the auxiliary film, a lower end portion of the auxiliary film, the first sacrifice film, the second sacrifice film, and the third sacrifice film, while leaving the auxiliary film inside the through hole on the vibrating plate, with a use of an etching fluid including hydrogen fluoride.

2. The method for fabricating a vibrator according to claim 1, wherein
a height position of a bottom surface of the through hole is set at a position downward away from a bottom surface of the vibrating plate by a film thickness dimension to be etched at a lower end portion of the auxiliary film in the etching such that a bottom surface of the vibrating plate and a lower end position of the auxiliary film inside the through hole are aligned with each other after the etching process.

3. The method for fabricating a vibrator according to claim 1, wherein
the second film thickness dimension is set to have a same dimension as a film thickness dimension to be etched at an upper end portion of the auxiliary film in the etching such that a top surface of the vibrating plate and an upper end position of the auxiliary film inside the through hole are aligned with each other after the etching process.

4. The method for fabricating a vibrator according to claim 2, wherein
the second film thickness dimension is set to have a same dimension as a film thickness dimension to be etched at an upper end portion of the auxiliary film in the etching such that a top surface of the vibrating plate and an upper end position of the auxiliary film inside the through hole are aligned with each other after the etching process.

5. The method for fabricating a vibrator according to claim 1, wherein
the filling-in forms the auxiliary film inside the through hole and on a surface of the second sacrifice film by supplying a processing gas including silicon and an oxidizing gas for oxidizing the processing gas onto a superficial layer side of the second sacrifice film, and
the method further comprises etching an excess of the auxiliary film formed on a surface of the second sacrifice film and an upper layer portion of the second sacrifice film after the filling-in, so as to adjust a height dimension of the auxiliary film protruding above an upper end position of the vibrating plate.

6. The method for fabricating a vibrator according to claim 2, wherein
the filling-in forms the auxiliary film inside the through hole and on a surface of the second sacrifice film by supplying a processing gas including silicon and an oxidizing gas for oxidizing the processing gas onto a superficial layer side of the second sacrifice film, and
the method further comprises etching an excess of the auxiliary film formed on a surface of the second sacrifice film and an upper layer portion of the second sacrifice film after the filling-in, so as to adjust a height dimension of the auxiliary film protruding above an upper end position of the vibrating plate.

7. The method for fabricating a vibrator according to claim 5, wherein
the adjusting the height dimension protrudes the upper end portion of the auxiliary film above the vibrating plate by a film thickness dimension to be etched at the upper end portion of the auxiliary film in the etching process such that the top surface of the vibrating plate and the upper end position of the auxiliary film inside the through hole are aligned with each other after the etching process.

8. The method for fabricating a vibrator according to claim 6, wherein
the adjusting the height dimension protrudes the upper end portion of the auxiliary film above the vibrating plate by a film thickness dimension to be etched at the upper end portion of the auxiliary film in the etching process such that the top surface of the vibrating plate and the upper end position of the auxiliary film inside the through hole are aligned with each other after the etching process.

9. The method for fabricating a vibrator according to claim 1, wherein
the first the sacrifice film and the second sacrifice film each include at least one of boron, phosphorus, sodium oxide, potassium oxide and calcium oxide in addition to silicon and oxygen; and
the auxiliary film is a silicon oxide film made up of silicon and oxygen.

10. The method for fabricating a vibrator according to claim 2, wherein
the first the sacrifice film and the second sacrifice film each include at least one of boron, phosphorus, sodium oxide, potassium oxide and calcium oxide in addition to silicon and oxygen; and
the auxiliary film is a silicon oxide film made up of silicon and oxygen.

11. The method for fabricating a vibrator according to claim 1, wherein
at least one of a composition of the etching fluid and a composition of the first sacrifice film is set such that an etching speed of the first sacrifice film at a time of usage of the etching fluid becomes 50 times or more of an etching speed of the auxiliary film.

12. The method for fabricating a vibrator according to claim 2, wherein
at least one of a composition of the etching fluid and a composition of the first sacrifice film is set such that an etching speed of the first sacrifice film at a time of usage of the etching fluid becomes 50 times or more of an etching speed of the auxiliary film.
